(19) United States
(12) Patent Application Publication
(10) Pub. No.: US 2024/0048117 A1
(43) Pub. Date: Feb. 8, 2024

(54) ACOUSTIC WAVE DEVICE

(71) Applicant: Murata Manufacturing Co., Ltd., Nagaokakyo-shi (JP)

(72) Inventors: Kentaro NAKAMURA, Nagaokakyo-shi (JP); Hideki IWAMOTO, Nagaokakyo-shi (JP)

(21) Appl. No.: 18/381,672

(22) Filed: Oct. 19, 2023

Related U.S. Application Data
(63) Continuation of application No. PCT/JP2022/023430, filed on Jun. 10, 2022.

(30) Foreign Application Priority Data
Jun. 16, 2021 (JP) 2021-100359

(51) Int. Cl. H03H 9/02; H03H 9/145

(52) U.S. Cl. CPC H03H 9/02228; H03H 9/02559; H03H 9/02574; H03H 9/14541

(57) ABSTRACT

An acoustic wave device includes a support substrate, an intermediate layer on the support substrate, a piezoelectric layer on the intermediate layer and including first and second principal surfaces opposed to each other, a first IDT electrode on the first principal surface of the piezoelectric layer, and a second IDT electrode on the second principal surface of the piezoelectric layer to be opposed to the first IDT electrode. The support substrate is a quartz substrate with Euler angles (ϕ, θ, ψ) of about 0°±10°, 70°≤θ≤170°, 90°±10°.

### CROSS REFERENCE TO RELATED APPLICATIONS

This application claims the benefit of priority to Japanese Patent Application No. 2021-100359 filed on Jun. 16, 2021 and is a Continuation application of PCT Application No. PCT/JP2022/023430 filed on Jun. 10, 2022. The entire contents of each application are hereby incorporated herein by reference.

### BACKGROUND OF THE INVENTION

### 1. Field of the Invention

The present invention relates to an acoustic wave device.

### 2. Description of the Related Art

Acoustic wave devices have heretofore been widely used in filters of cellular phones and the like. The Japanese Unexamined Patent Application Publication No. 2019-145895 describes an example of an acoustic wave device. This acoustic wave device includes a multilayer substrate formed from a support substrate, a high acoustic velocity film, a low acoustic velocity film, and a piezoelectric layer. An IDT electrode is provided on the piezoelectric layer. Silicon is used for the support substrate. SiNₓ is used for the high acoustic velocity film so as to satisfy x<0.67, thus suppressing a high-order mode and suppressing a variation in frequency in the high-order mode.

### SUMMARY OF THE INVENTION

However, the acoustic wave device of Japanese Unexamined Patent Application Publication No. 2019-145895 cannot sufficiently suppress the high mode in a wide band. In addition, the acoustic device also has a difficulty in sufficiently increasing frequency-temperature characteristics.

Preferred embodiments of the present invention provide acoustic wave devices each of which is capable of suppressing a high-order mode in a wide band and improving frequency-temperature characteristics.

An acoustic wave device according to a preferred embodiment of the present invention includes a support substrate, an intermediate layer on the support substrate, a piezoelectric layer on the intermediate layer and including a first principal surface and a second principal surface opposed to each other, a first IDT electrode on the first principal surface of the piezoelectric layer, and a second IDT electrode on the second principal surface of the piezoelectric layer and opposite to the first IDT electrode, wherein the support substrate is a quartz substrate with Euler angles (ϕ, θ, ψ) of about 0°±10°, 70°≤θ≤170°, 90°±10°.

An acoustic wave device according to a preferred embodiment of the present invention includes a support substrate, an intermediate layer on the support substrate, a piezoelectric layer on the intermediate layer and including a first principal surface and a second principal surface opposed to each other, a first IDT electrode on the first principal surface of the piezoelectric layer, and a second IDT electrode on the second principal surface of the piezoelectric layer and opposite to the first IDT electrode, wherein the intermediate layer includes a high acoustic velocity layer directly contacting the support substrate, an acoustic velocity of a bulk wave propagating through the high acoustic velocity layer is higher than an acoustic velocity of an acoustic wave propagating through the piezoelectric layer, the support substrate is a quartz substrate, and when λ is a wavelength defined by an electrode finger pitch of the first IDT electrode, a material and a range of thickness of the high acoustic velocity layer are any of combinations in Table 1.

TABLE 1

| Material | Range of thickness t |
|---|---|
| silicon nitride | t ≥ 0.3λ |
| aluminum oxide | t ≥ 0.5λ |
| polycrystalline silicon | t ≥ 0.45λ |
| silicon carbide | t ≥ 0.4λ |

An acoustic wave device according to a preferred embodiment of the present invention includes a support substrate, an intermediate layer on the support substrate, a piezoelectric layer on the intermediate layer and including a first principal surface and a second principal surface opposed to each other, a first IDT electrode on the first principal surface of the piezoelectric layer, and a second IDT electrode on the second principal surface of the piezoelectric layer to be opposed to the first IDT electrode, wherein the intermediate layer includes a high acoustic velocity layer directly contacting the support substrate, an acoustic velocity of a bulk wave propagating through the high acoustic velocity layer is higher than an acoustic velocity of an acoustic wave propagating through the piezoelectric layer, and the support substrate is a quartz substrate with Euler angles (ϕ, θ, ψ) of about 0°±10°, 180°≤θ≤240°, 90°±10°.

An acoustic wave device according to a preferred embodiment of the present invention includes a support substrate, an intermediate layer on the support substrate, a piezoelectric layer on the intermediate layer and including a first principal surface and a second principal surface opposed to each other, a first IDT electrode on the first principal surface of the piezoelectric layer, and a second IDT electrode on the second principal surface of the piezoelectric layer and opposite to the first IDT electrode, wherein the intermediate layer includes a high acoustic velocity layer directly contacting the support substrate, an acoustic velocity of a bulk wave propagating through the high acoustic velocity layer is higher than an acoustic velocity of an acoustic wave propagating through the piezoelectric layer, and the support substrate is a quartz substrate with Euler angles (ϕ, θ, ψ) of about 0°±10°, 100°≤θ≤150°, 0°±10°.

The acoustic wave devices according to preferred embodiments of the present invention are able to suppress a high-order mode in a wide band and improve frequency-temperature characteristics.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a front sectional view of an acoustic wave device according to a first preferred embodiment of the present invention.

FIG. 2 is a plan view of the acoustic wave device according to the first preferred embodiment of the present invention.

FIG. 3 is a graph showing phase characteristics of the first preferred embodiment of the present invention, a first comparative example, and a second comparative example of the present invention.

FIG. 4 is a graph showing a relation between a thickness of a silicon nitride layer as a high acoustic velocity layer in the first preferred embodiment of the present invention and |Z| ratio thereof.

FIG. 5 is a graph showing a relation between a thickness of an aluminum oxide layer as the high acoustic velocity layer in the first preferred embodiment of the present invention and the |Z| ratio thereof.

FIG. 6 is a graph showing a relation between a thickness of a polycrystalline silicon layer as the high acoustic velocity layer in the first preferred embodiment of the present invention and the |Z| ratio thereof.

FIG. 7 is a graph showing a relation between a thickness of a silicon carbide layer as the high acoustic velocity layer in the first preferred embodiment of the present invention and the |Z| ratio thereof.

FIG. 8 is a graph showing a relation between θ in Euler angles of quartz of a support substrate of a second preferred embodiment of the present invention and a Q factor thereof.

FIG. 9 is a front sectional view of an acoustic wave device according to a third preferred embodiment of the present invention.

FIG. 10 is a graph showing a relation between θ in the Euler angles of quartz of a support substrate of the third preferred embodiment of the present invention and the Q factor thereof.

FIG. 11 is a graph showing relations between θ in the Euler angles of quartz of a quartz substrate and acoustic velocities of respective waves propagating through the quartz substrate.

FIG. 12 is a graph showing a relation between θ in the Euler angles of quartz of a support substrate of a modification of the third preferred embodiment of the present invention and the Q factor thereof.

### DETAILED DESCRIPTION OF THE PREFERRED EMBODIMENTS

The present invention will be clarified below by describing specific preferred embodiments of the present invention with reference to the drawings.

It is to be noted that each of the preferred embodiments described in the present specification is exemplary, and that it is possible to replace or combine elements or features of configurations in preferred embodiments different from each other.

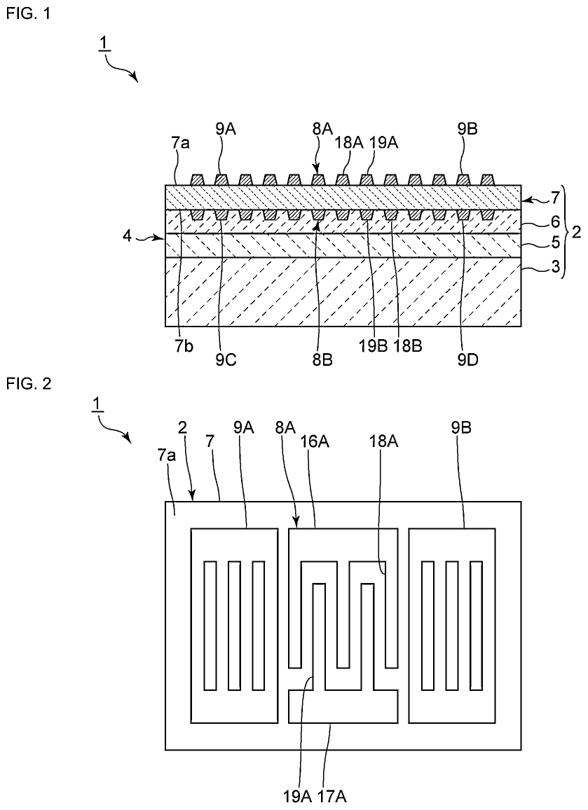

FIG. 1 is a front sectional view of an acoustic wave device according to a first preferred embodiment of the present invention.

An acoustic wave device 1 includes a piezoelectric substrate 2. In the present preferred embodiment, the piezoelectric substrate 2 includes a support substrate 3, an intermediate layer 4, and a piezoelectric layer 7. To be more precise, the intermediate layer 4 is provided on the support substrate 3. The piezoelectric layer 7 is provided on the intermediate layer 4. The support substrate 3 is a quartz substrate.

The piezoelectric layer 7 includes a first principal surface 7a and a second principal surface 7b. The first principal surface 7a and the second principal surface 7b are opposed to each other. Of the first principal surface 7a and the second principal surface 7b, the second principal surface 7b is a principal surface on the support substrate 3 side. In the present preferred embodiment, the piezoelectric layer 7 is a lithium tantalate layer. Note that the material of the piezoelectric layer 7 is not limited to the above-described material and it is also possible to use lithium niobate or the like.

Both of the principal surfaces of the piezoelectric layer 7 are provided with IDT electrodes. To be more precise, the first principal surface 7a is provided with a first IDT electrode 8A. The second principal surface 7b is provided with a second IDT electrode 8B. The first IDT electrode 8A and the second IDT electrode 8B are opposed to each other while interposing the piezoelectric layer 7 in between. An acoustic wave is excited by applying an alternating-current voltage to each IDT electrode. The acoustic wave device 1 uses an SH mode as a main mode. Note that the mode to be used as the main mode is not limited to the SH mode. A pair of a reflector 9A and a reflector 9B are provided on the first principal surface 7a on both sides of the first IDT electrode 8A in a direction in which an acoustic wave propagates. A pair of a reflector 9C and a reflector 9D are provided on the second principal surface 7b on both sides of the second IDT electrode 8B in the direction in which an acoustic wave propagates. As described above, the acoustic wave device 1 of the present preferred embodiment is a surface acoustic wave resonator. Nevertheless, the acoustic wave devices according to preferred embodiments of the present invention are not limited to the acoustic wave resonators and may be filter devices or multiplexers including multiple acoustic wave resonators.

The reflector 9A, the reflector 9B, the reflector 9C, and the reflector 9D may have a potential equal to that of first electrode fingers 18A of the first IDT electrode 8A or a potential equal to that of second electrode fingers 19A thereof. Alternatively the reflectors mentioned above may each have a potential equal to that of first electrode fingers 18B of the second IDT electrode 8B or a potential equal to that of second electrode fingers 19B thereof. The reflectors mentioned above may each be a floating electrode. Here, a floating electrode is an electrode which is not connected to either a hot potential or a ground potential. Each of the IDT electrodes and each of the reflectors may include a single-layered metal film or a multilayered metal film.

FIG. 2 is a plan view of the acoustic wave device according to the first preferred embodiment.

The first IDT electrode 8A includes a first busbar 16A, a second busbar 17A, the first electrode fingers 18A, and the second electrode fingers 19A. The first busbar 16A and the second busbar 17A are opposed to each other. One end of each of the first electrode fingers 18A is connected to the first busbar 16A. One end of each of the second electrode fingers 19A is connected to the second busbar 17A. The first electrode fingers 18A and the second electrode fingers 19A are interdigitated with one another.

The second IDT electrode 8B shown in FIG. 1 also has the same configuration as that of the first IDT electrode 8A. To be more precise, the second IDT electrode 8B includes a first busbar, a second busbar, the first electrode fingers 18B, and the second electrode fingers 19B.

Centers of the respective electrode fingers of the first IDT electrode 8A and centers of the respective electrode fingers of the second IDT electrode 8B overlap one another in plan view. Nevertheless, the centers of the respective electrode fingers of the first IDT electrode 8A and the centers of the respective electrode fingers of the second IDT electrode 8B do not always have to overlap one another in plan view. In the present specification, “in plan view” refers to a direction viewed from above in FIG. 1.

When X is a wavelength defined by an electrode finger pitch of the first IDT electrode 8A, a thickness of the piezoelectric layer 7 in the acoustic wave device 1 is less than or equal to about 1λ, for example. Nevertheless, the thickness of the piezoelectric layer 7 is not limited to the aforementioned value. In the present preferred embodiment, the electrode finger pitches of the first IDT electrode 8A and the second IDT electrode 8B are equal. Here, the electrode finger pitch is a center-to-center distance between electrode fingers that are adjacent to each other. In the present specification, “the electrode finger pitches being equal” also includes a state where the electrode finger pitches are different within an error range of such a level that does not affect electrical characteristics of the acoustic wave device. As shown in FIG. 1, a shape of a transverse section of each electrode finger in the first IDT electrode 8A and the second IDT electrode 8B is a trapezoid. Nonetheless, the shape of the transverse section of each electrode finger is not limited to the above-mentioned shape and may be a rectangle, for example.

In the present preferred embodiment, the intermediate layer 4 is a multilayer body including a high acoustic velocity layer 5 and a low acoustic velocity layer 6. The high acoustic velocity layer 5 is provided directly on the support substrate 3.

The high acoustic velocity layer 5 is a layer having a relatively high acoustic velocity. To be more precise, an acoustic velocity of a bulk wave propagating through the high acoustic velocity layer 5 is higher than an acoustic velocity of an acoustic wave propagating through the piezoelectric layer 7. In the present preferred embodiment, silicon nitride is used for the high acoustic velocity layer 5. The material of the high acoustic velocity layer 5 is not limited to this, and any of aluminum oxide, polycrystalline silicon, and silicon carbide can be used instead.

The low acoustic velocity layer 6 is a layer having a relatively low acoustic velocity. To be more precise, an acoustic velocity of a bulk wave propagating through the low acoustic velocity layer 6 is lower than an acoustic velocity of a bulk wave propagating through the piezoelectric layer 7. In the present preferred embodiment, silicon oxide is used for the low acoustic velocity layer 6. The material of the low acoustic velocity layer 6 is not limited to this, and a material containing any of glass, silicon oxynitride, lithium oxide, tantalum pentoxide, and a compound obtained by adding fluorine, carbon, or boron to silicon oxide as a major component can be used, for example.

The present preferred embodiment preferably includes the following characteristic configurations 1) to 3): 1) that the piezoelectric substrate 2 is a multilayer substrate including the support substrate 3, the intermediate layer 4, and the piezoelectric layer 7, in which the intermediate layer 4 includes the high acoustic velocity layer 5 and the material and a range of thickness of the high acoustic velocity layer 5 are any of combinations shown in the Table 2 below; 2) that the IDT electrodes are provided on both of the principal surfaces of the piezoelectric layer 7; and 3) that the support substrate 3 is a quartz substrate. Since the support substrate 3 is the quartz substrate in the present preferred embodiment, it is possible to reduce an absolute value of a temperature coefficient of frequency (TCF) of the acoustic wave device 1. Thus, frequency-temperature characteristics can be improved. Moreover, provision of the IDT electrodes on both of the principal surfaces of the piezoelectric layer 7 makes it possible to suppress a high-order mode in a wide band. In addition, since the material and the range of thickness of the high acoustic velocity layer 5 are any of the combinations shown in Table 2, it is possible to effectively increase a Q factor. Here, the thickness of the high acoustic velocity layer 5 is defined as t.

TABLE 2

| Material | Range of thickness t |
|---|---|
| silicon nitride | t ≥ 0.3λ |
| aluminum oxide | t ≥ 0.5λ |
| polycrystalline silicon | t ≥ 0.45λ |
| silicon carbide | t ≥ 0.4λ |

Details of the effect of suppressing the high-order mode and the effect of increasing the Q factor will be shown below.

The effect of suppressing the high-order mode will be demonstrated by comparing the first preferred embodiment with a first comparative example and a second comparative example. The first comparative example is different from the first preferred embodiment in that the support substrate is a silicon substrate and the second IDT electrodes are not provided. The second comparative example is different from the first preferred embodiment in that the support substrate is a silicon substrate. Here, in the first preferred embodiment, the first comparative example, and the second comparative example, the high acoustic velocity layer is a silicon nitride layer, the low acoustic velocity layer is a silicon oxide layer, and the piezoelectric layer is a lithium tantalate layer. To be more precise, the high acoustic velocity layer is the SiN layer, the low acoustic velocity layer is the SiO₂ layer, and the piezoelectric layer is the LiTaO₃ layer. In the first preferred embodiment, Euler angles (ϕ, θ, ψ) of quartz used for the support substrate 3 are (0°, 90°, 90°).

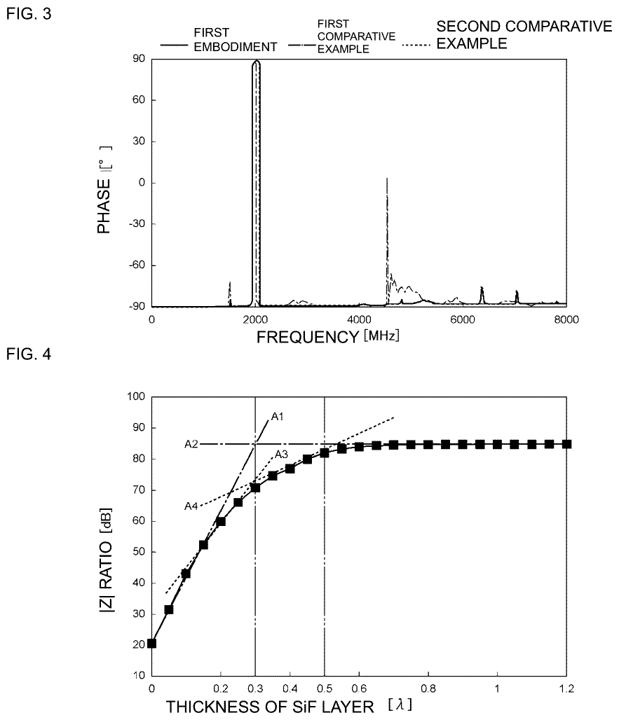

FIG. 3 is a graph showing phase characteristics of the first preferred embodiment, the first comparative example, and the second comparative example.

As shown in FIG. 3, it was discovered that the first comparative example cannot sufficiently suppress the high-order mode. On the other hand, it was discovered that the high-order mode is suppressed in a wide band in the first preferred embodiment. Note that the phase characteristics of the second comparative example are not significantly different from those of the first preferred embodiment. Suppression of the high-order mode in the first preferred embodiment and the second comparative example is attributed to provision of the IDT electrodes on both of the principal surfaces of the piezoelectric layer as mentioned above. What is more, the support substrate is the quartz substrate in the first preferred embodiment. In this way, it is also possible to enhance the frequency-temperature characteristics.

Furthermore, relations between the thickness and |Z| ratio [dB] of the high acoustic velocity layer 5 depending on the materials of the high acoustic velocity layer 5 will be shown below in FIGS. 4 to 7. The |Z| ratio is an impedance ratio. Specifically, the |Z| ratio is a value obtained by dividing impedance at an anti-resonant frequency by impedance at a resonant frequency. The Q factor is larger as the |Z| ratio is larger. In this case, energy of the acoustic wave can be effectively confined on the piezoelectric layer 7 side.

The high acoustic velocity layer 5 is formed from the silicon nitride layer, the aluminum oxide layer, the polycrystalline silicon layer, or the silicon carbide layer. To be more precise, the high acoustic velocity layer 5 is formed from the SiN layer, the Al₂O₃ layer, the poly-Si layer, or the SiC layer. In each case, the |Z| ratio is measured every time the thickness of the high acoustic velocity layer 5 is changed. To be more precise, the thickness of the high acoustic velocity layer 5 is changed in increments of about 0.1 μm in a range from greater than or equal to about 0 μm to less than or equal to about 6 μm, for example. Since λ is set equal to about 2 μm, this is equivalent to changing the thickness of the high acoustic velocity layer 5 in increments of about 0.05λ in a range from greater than or equal to about 0λ to less than or equal to about 3λ, for example. Here, the Euler angles (ϕ, θ, ψ) of quartz of the support substrate 3 are (0°, 200°, 90°), for example. Meanwhile, 30Y0X LiTaO₃ is used as the piezoelectric layer 7, for example.

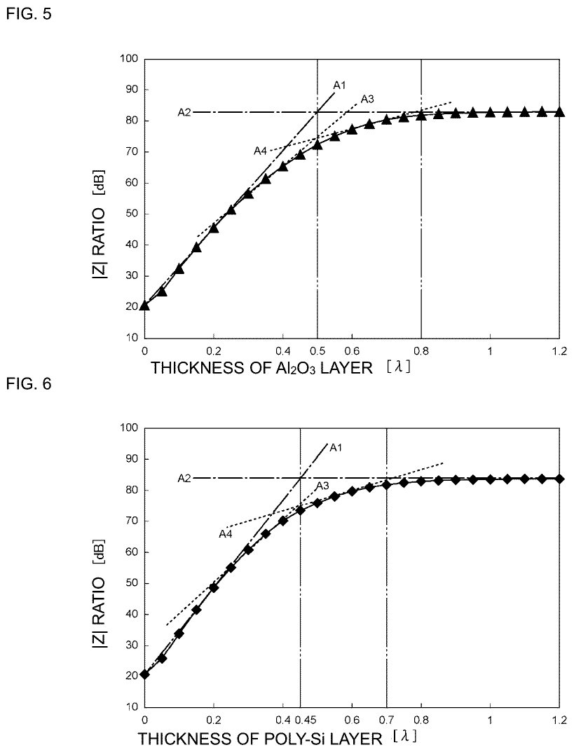

FIG. 4 is a graph showing a relation between the thickness of the silicon nitride layer as the high acoustic velocity layer in the first preferred embodiment and the |Z| ratio thereof. In FIG. 4, the |Z| ratio is constant in a range where the thickness is greater than or equal to about 1.2λ, for example. Accordingly, a range of the thickness in excess of about 1.2λ is omitted. The same applies to FIGS. 5 to 7.

As shown in FIG. 4, it was discovered that the |Z| ratio grows larger as the thickness of the silicon nitride layer is larger. The thickness of the silicon nitride layer is preferably greater than or equal to about 0.3λ, for example. The |Z| ratio can be effectively increased higher than about 70 dB in the case where the thickness of the silicon nitride layer is greater than or equal to about 0.3λ, for example. Thus, the Q factor can be increased effectively.

When the silicon nitride layer is sufficiently thick, the |Z| ratio remains constant. Here, a chain line A1 and a chain line A2 as well as a dashed line A3 and a dashed line A4 in FIG. 4 show inclinations of changes in |Z| ratio with respect to changes in thickness of the silicon nitride layer. Specifically, the chain line A1 shows the inclination in the case where the thickness of the silicon nitride layer is close to 0. The chain line A2 shows the inclination at the thickness of the silicon nitride layer with which the |Z| ratio becomes constant. A point of intersection between the chain line A1 and the chain line A2 is located at a point where the thickness of the silicon nitride layer preferably is equal to about 0.3λ, for example. The dashed line A3 shows the inclination at the thickness in the vicinity of the above-mentioned point of intersection, where the thickness is less than or equal to the thickness at the point of intersection. The dashed line A4 shows the inclination at the thickness in the vicinity of the above-mentioned point of intersection, where the thickness is greater than or equal to the thickness at the point of intersection. Using the dashed line A3 and the dashed line A4, it is possible to confirm that the inclination in the case where the thickness of the silicon nitride layer is greater than or equal to about 0.3λ is considerably smaller than the inclination in the case where the thickness is less than or equal to about 0.3λ, for example. Accordingly, it is possible to stabilize the |Z| ratio and to stabilize the electrical characteristics in the case where the thickness of the silicon nitride layer is greater than or equal to about 0.3λ, for example.

The thickness of the silicon nitride layer is more preferably greater than or equal to about 0.5λ, for example. In this way, the |Z| ratio can be brought close to a maximum value. To be more precise, the |Z| ratio can be set greater than or equal to about 96% of the maximum value of the |Z| ratio, for example. Thus, the Q factor can further be increased.

The chain lines A1 and the chain lines A2 as well as the dashed lines A3 and the dashed lines A4 in the following FIGS. 5 to 7 show the same inclinations as those of the corresponding chain lines and the corresponding dashed lines in FIG. 4. Specifically, the chain line A1 shows the inclination of the change in |Z| ratio with respect to the change in thickness of the high acoustic velocity layer in the case where the thickness of the high acoustic velocity layer is close to 0. The chain line A2 shows the inclination at the thickness of the high acoustic velocity layer with which the |Z| ratio becomes constant. The dashed line A3 shows the inclination at the thickness of the high acoustic velocity layer in the vicinity of the point of intersection between the chain line A1 and the chain line A2, where the thickness is less than or equal to the thickness at the point of intersection. The dashed line A4 shows the inclination at the thickness of the high acoustic velocity layer in the vicinity of the point of intersection between the chain line A1 and the chain line A2, where the thickness is greater than or equal to the thickness at the point of intersection.

FIG. 5 is a graph showing a relation between the thickness of the aluminum oxide layer as the high acoustic velocity layer in the first preferred embodiment and the |Z| ratio thereof.

As shown in FIG. 5, it was discovered that the |Z| ratio can be effectively increased higher than about 70 dB in the case where the thickness of the aluminum oxide layer is greater than or equal to about 0.5λ, for example. The chain line A1 and the chain line A2 in FIG. 5 cross each other at a point where the thickness of the aluminum oxide layer is equal to about 0.5λ, for example. Using the dashed line A3 and the dashed line A4, it is possible to confirm that the inclination of the |Z| ratio in the case where the thickness of the aluminum oxide layer is greater than or equal to about 0.5λ is considerably smaller than the inclination in the case where the thickness of the aluminum oxide layer is less than or equal to about 0.5λ, for example. As described above, the thickness of the aluminum oxide layer is preferably greater than or equal to about 0.5λ, for example. In this way, the |Z| ratio can be increased effectively so that the Q factor can be increased effectively. In addition, it is possible to stabilize the |Z| ratio and to stabilize the electrical characteristics.

The thickness of the aluminum oxide layer is more preferably greater than or equal to about 0.8λ, for example. In this way, the |Z| ratio can be set greater than or equal to about 96% of the maximum value of the |Z| ratio, for example. Thus, the Q factor can further be increased.

FIG. 6 is a graph showing a relation between the thickness of the polycrystalline silicon layer as the high acoustic velocity layer in the first preferred embodiment and the |Z| ratio thereof.

As shown in FIG. 6, it was discovered that the |Z| ratio can be effectively increased higher than about 70 dB in the case where the thickness of the polycrystalline silicon layer is greater than or equal to about 0.45λ, for example. The chain line A1 and the chain line A2 in FIG. 6 cross each other at a point where the thickness of the polycrystalline silicon layer is equal to about 0.45λ, for example. Using the dashed line A3 and the dashed line A4, it is possible to confirm that the inclination of the |Z| ratio in the case where the thickness of the polycrystalline silicon layer is greater than or equal to about 0.45λ is considerably smaller than the inclination in the case where the thickness of the polycrystalline silicon layer is less than or equal to about 0.45λ, for example. As described above, the thickness of the polycrystalline silicon layer is preferably greater than or equal to about 0.45λ, for example. In this way, the |Z| ratio can be increased effectively so that the Q factor can be increased effectively. In addition, it is possible to stabilize the |Z| ratio and to stabilize the electrical characteristics.

The thickness of the polycrystalline silicon layer is more preferably greater than or equal to about 0.7λ, for example. In this way, the |Z| ratio can be set greater than or equal to about 96% of the maximum value of the |Z| ratio, for example. Thus, the Q factor can further be increased.

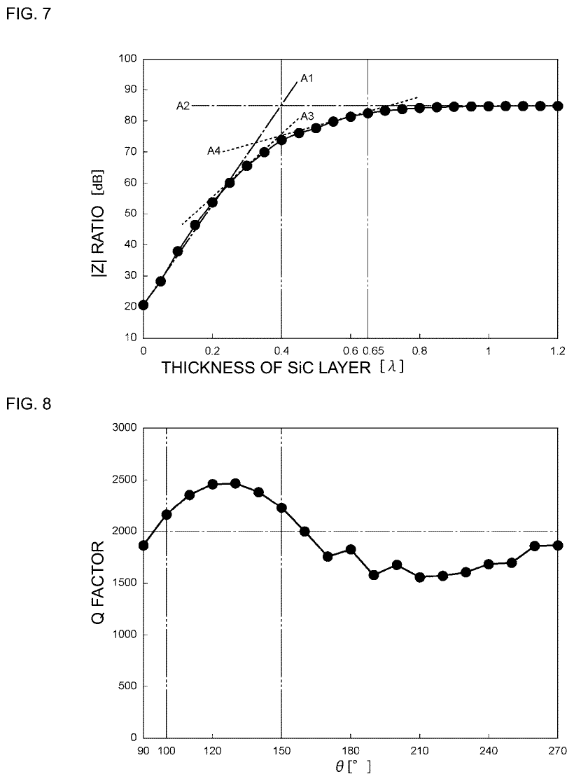

FIG. 7 is a graph showing a relation between the thickness of the silicon carbide layer as the high acoustic velocity layer in the first preferred embodiment and the |Z| ratio thereof.

As shown in FIG. 7, it was discovered that the |Z| ratio can be effectively increased higher than about 70 dB in the case where the thickness of the silicon carbide layer is greater than or equal to about 0.4λ, for example. The chain line A1 and the chain line A2 in FIG. 7 cross each other at a point where the thickness of the silicon carbide layer is equal to about 0.4λ, for example. Using the dashed line A3 and the dashed line A4, it is possible to confirm that the inclination of the |Z| ratio in the case where the thickness of the silicon carbide layer is greater than or equal to about 0.4λ is considerably smaller than the inclination in the case where the thickness of the silicon carbide layer is less than or equal to about 0.4λ, for example. As described above, the thickness of the silicon carbide layer is preferably greater than or equal to about 0.4λ, for example. In this way, the |Z| ratio can be increased effectively so that the Q factor can be increased effectively. In addition, it is possible to stabilize the |Z| ratio and to stabilize the electrical characteristics.

The thickness of the silicon carbide layer is more preferably greater than or equal to about 0.65λ, for example. In this way, the |Z| ratio can be set greater than or equal to about 96% of the maximum value of the |Z| ratio, for example. Thus, the Q factor can further be increased.

As described above, the material and the range of thickness of the high acoustic velocity layer 5 are preferably any of the combinations shown in the foregoing Table 2. Thus, it is possible to effectively increase the Q factor. The material and the range of thickness of the high acoustic velocity layer 5 are more preferably any of the combinations shown in the following Table 3. In this way, it is possible to further increase the Q factor, and to stabilize the electrical characteristics.

TABLE 3

| Material | Range of thickness t |
|---|---|
| silicon nitride | t ≥ 0.5λ |
| aluminum oxide | t ≥ 0.8λ |
| polycrystalline silicon | t ≥ 0.7λ |
| silicon carbide | t ≥ 0.65λ |

On the other hand, the thickness of the high acoustic velocity layer 5 is preferably less than or equal to about 4 μm, for example. In manufacturing of the acoustic wave device, the high acoustic velocity layer 5 is formed on a wafer. By setting the high acoustic velocity layer 5 less than or equal to about 4 μm, for example, it is possible to suppress a stress caused by formation of the high acoustic velocity layer 5, and to suppress warpage of the wafer. Accordingly, the wafer on which the high acoustic velocity layer 5 is formed can be appropriately transported at the time of manufacture, thereby enhancing productivity.

As shown in FIG. 1, in the first preferred embodiment, the first IDT electrode 8A and the second IDT electrode 8B are opposed to each other while interposing the piezoelectric layer 7 in between. In this way, a device capacitance can be increased without forming the large acoustic wave device 1. Accordingly, it is possible to downsize the acoustic wave device 1 in order to obtain a desired device capacitance.

In a preferred embodiment of the present invention, the material and the range of thickness of the high acoustic velocity layer are not limited to the combinations shown in Table 2 and Table 3. It is possible to improve the frequency-temperature characteristics, to suppress the high-order mode in a wide band, and to increase the Q factor effectively even in a case other than the first preferred embodiment. A configuration of a second preferred embodiment will be described below as such an example.

In the second preferred embodiment, the configuration of the layers is the same as that of the first preferred embodiment. For this reason, the configuration of the second preferred embodiment will be described while incorporating FIG. 1 herein by reference. The second preferred embodiment is different from the first preferred embodiment in that the Euler angles (ϕ, θ, ψ) of quartz of the support substrate 3 are in predetermined ranges. Except for this point, the acoustic wave device of the second preferred embodiment has the same configuration as that of the acoustic wave device 1 of the first preferred embodiment. In other words, the material and the range of thickness of the high acoustic velocity layer 5 may be any of the combinations shown in FIG. 2 in the second preferred embodiment as well.

The second preferred embodiment preferably includes the following characteristic configurations 1) to 3): 1) that the piezoelectric substrate 2 is a multilayer substrate including the support substrate 3, the intermediate layer 4, and the piezoelectric layer 7, in which the intermediate layer 4 includes the high acoustic velocity layer 5; 2) that the IDT electrodes are provided on both of the principal surfaces of the piezoelectric layer 7; and 3) that the support substrate 3 is a quartz substrate, and the Euler angles (ϕ, θ, ψ) of quartz of the support substrate 3 are about 0°±10°, 100°≤θ≤150°, 0°±10°. Thus, the frequency-temperature characteristics can be improved and the high-order mode can be suppressed in a wide band as with the first preferred embodiment. In addition, the Q factor can be effectively increased since the Euler angles of quartz of the support substrate 3 are in the above-mentioned ranges. The Q factor can be effectively increased likewise in a case where orientations of the Euler angles of quartz are equivalent to the above. Details of the effect of increasing the Q factor will be shown below.

The Q factor is measured every time θ in Euler angles (0°, θ, 0°) of quartz of the support substrate 3 is changed. To be more precise, θ is changed in increments of about 10° in a range from greater than or equal to about 90° to less than or equal to about 270°, for example.

FIG. 8 is a graph showing a relation between θ in the Euler angles of quartz of the support substrate of the second preferred embodiment and the Q factor thereof.

As shown in FIG. 8, it was discovered that the high Q factor greater than or equal to 2000 is observed in the range of about 100°≤θ≤150°, for example. It was also discovered that the Q factor does not significantly vary even when ϕ in the Euler angles (ϕ, θ, ψ) is changed within the range of about 0°±10°. Likewise, it was also discovered that the Q factor does not significantly vary even when ψ in the Euler angles is changed within the range of about 0°±10°. Accordingly, in the present preferred embodiment, the Q factor can be effectively increased by setting the Euler angles of quartz of the support substrate 3 to about 0°±10°, 100°≤θ≤150°, 0°±10°.

In the present preferred embodiment, the material of the high acoustic velocity layer 5 is not limited to a particular material. For example, a medium containing any of materials including silicon, aluminum oxide, silicon carbide, silicon nitride, silicon oxynitride, sapphire, lithium tantalate, lithium niobate, quartz, alumina, zirconia, cordierite, mullite, steatite, forsterite, magnesia, a diamond-like carbon (DLC) film, diamond, and the like as a main component can be used as the material of the high acoustic velocity layer 5.

Note that the intermediate layer 4 only needs to include the high acoustic velocity layer 5 and does not always have to include the low acoustic velocity layer 6 in the first preferred embodiment and the second preferred embodiment. In the meantime, an example in which the intermediate layer includes the low acoustic velocity layer but does not include the high acoustic velocity layer will be shown below.

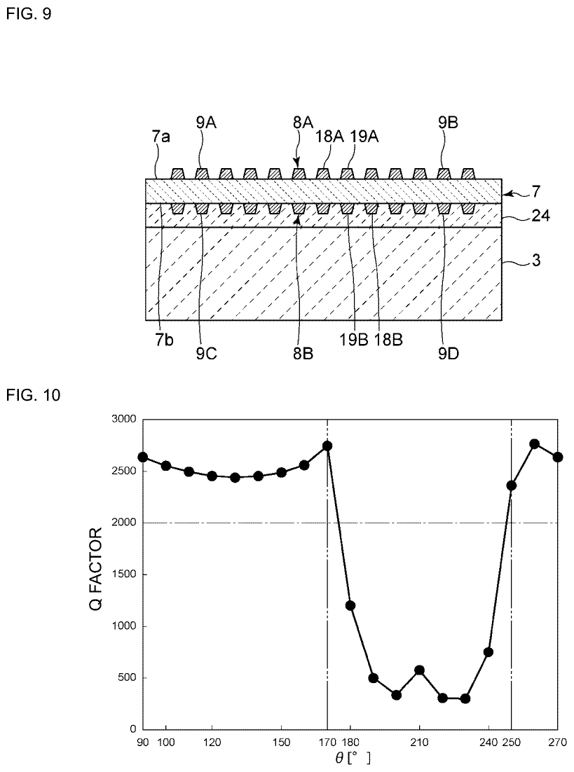

FIG. 9 is a front sectional view of an acoustic wave device according to a third preferred embodiment.

The present preferred embodiment is different from the first preferred embodiment in that an intermediate layer 24 is a low acoustic velocity layer. Specifically, the intermediate layer 24 includes the low acoustic velocity layer but does not include a high acoustic velocity layer. Except for this point, the acoustic wave device of the present preferred embodiment has the same configuration as that of the acoustic wave device 1 of the first preferred embodiment.

The present preferred embodiment preferably includes the following characteristic configurations 1) to 3): 1) that the piezoelectric substrate 2 is a multilayer substrate including the support substrate 3, the intermediate layer 24, and the piezoelectric layer 7; 2) that the IDT electrodes are provided on both of the principal surfaces of the piezoelectric layer 7; and 3) that the support substrate 3 is a quartz substrate, and the Euler angles (ϕ, θ, ψ) of quartz of the support substrate 3 are about 0°±10°, 70°≤θ≤170°, 90°±10°. Thus, the frequency-temperature characteristics can be improved and the high-order mode can be suppressed in a wide band as with the first preferred embodiment. In addition, the Q factor can be effectively increased since the Euler angles of quartz of the support substrate 3 are in the above-mentioned ranges. Details of the effect of increasing the Q factor will be shown below.

The Q factor is measured every time θ in Euler angles (0°, θ, 90°) of quartz of the support substrate 3 is changed. To be more precise, θ is changed in increments of about 10° in a range from greater than or equal to about 90° to less than or equal to about 270°, for example. Here, 90° is equivalent to 270° while 180° is equivalent to 0° due to the crystalline symmetry of quartz. Accordingly, an act of changing θ in a range from greater than or equal to 180° to less than or equal to 270° within the range from greater than or equal to 90° to less than or equal to 270° is equivalent to an act of changing θ in a range from greater than or equal to 0° to less than or equal to 90°. Therefore, the act of changing θ in the range from greater than or equal to 90° to less than or equal to 270° is equivalent to an act of changing θ in a range from greater than or equal to 0° to less than or equal to 180° as a whole.

FIG. 10 is a graph showing a relation between θ in the Euler angles of quartz of the support substrate of the third preferred embodiment and the Q factor thereof.

As shown in FIG. 10, it was discovered that the Q factor is high in ranges of 90°≤θ≤170° and 250°≤θ≤270°, for example. The Q factor is similarly high in the case where orientations of the Euler angles of quartz are equivalent to the above. Accordingly, the Q factor is high in a range of 70°≤θ≤170°, for example, due to the crystalline symmetry of quartz. As mentioned above, it was discovered that the Q factor does not significantly vary even when ϕ in the Euler angles (ϕ, θ, ψ) is changed within the range of about 0°±10°, for example. Likewise, it was also discovered that the Q factor does not significantly vary even when ψ in the Euler angles is changed within a range of about 90°±10°, for example. Accordingly, in the present preferred embodiment, the Q factor can be effectively increased by setting the Euler angles of quartz of the support substrate 3 to about 0°±10°, 70°≤θ≤170°, 90°±10°.

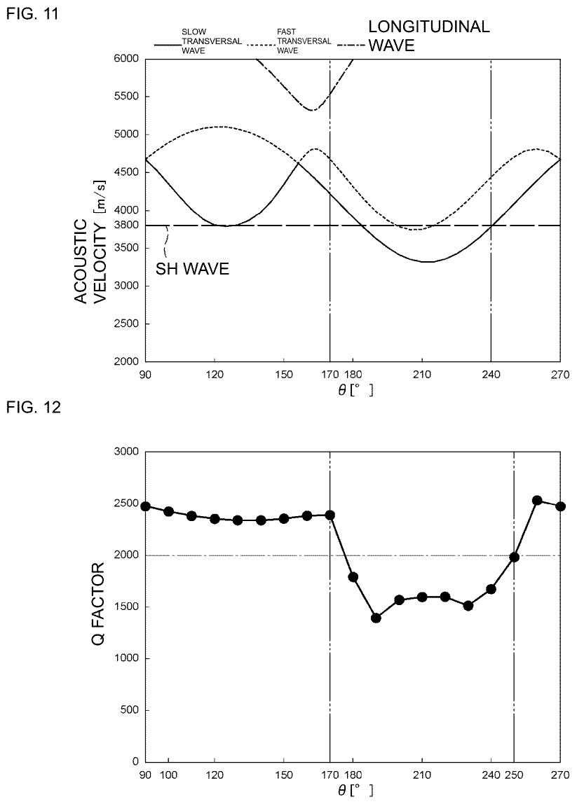

As described above, the present preferred embodiment can effectively increase the Q factor even though the intermediate layer 24 does not include the high acoustic velocity layer. This is due to the reason that the main mode can be confined on the piezoelectric layer 7 side since the Euler angles (ϕ, θ, ψ) of quartz of the support substrate 3 are in the above-mentioned ranges. To be more precise, as shown in FIG. 11, in the case where θ in the Euler angles (0°, θ, 90°) is in the ranges of 90°≤θ≤170° and 250°≤θ≤270°, for example, an acoustic velocity at which an SH wave being the main mode propagates is lower than or equal to an acoustic velocity at which a slow transversal wave propagates through the quartz substrate. Accordingly, the main mode is confined on the piezoelectric layer 7 side by setting θ in the above-mentioned ranges, whereby the Q factor is increased.

Here, as shown in FIG. 11, the acoustic velocity at which the SH wave being the main mode propagates is higher than the acoustic velocity at which the slow transversal wave propagates through the quartz substrate in the case where θ in the Euler angles (0°, θ, 90°) is in a range of 180°≤θ≤240°, for example. In this instance, the main mode can be confined on the piezoelectric layer 7 side by causing the intermediate layer 4 to include the high acoustic velocity layer 5, so that the Q factor can be increased as shown in FIG. 1. Accordingly, in the examples of the configurations of which the |Z| ratios are shown in FIGS. 4 to 7, for instance, the Q factor can be increased in the case where the Euler angles of quartz of the support substrate 3 are about 0°±10°, 180°≤θ≤240°, 0°±90°. Here, the intermediate layer 4 may include the low acoustic velocity layer 6 in addition to the high acoustic velocity layer 5.

The intermediate layer 24 is preferably a silicon oxide layer. Thus, the absolute value of the temperature coefficient of frequency can be more reliably set smaller, thereby improving the frequency-temperature characteristics more reliably.

Nevertheless, the acoustic wave device having the characteristics of the present preferred embodiment may also include the high acoustic velocity layer as with the first preferred embodiment and the second preferred embodiment. An acoustic wave device being different only in that the intermediate layer includes the high acoustic velocity layer will be referred to as an acoustic wave device of a modification of the present preferred embodiment. In this case, a configuration of the layers in the present modification is the same as the configuration of the layers shown in FIG. 1. The following shows the fact that the present modification can also increase the Q factor effectively.

In the same manner as the case of obtaining the relation shown in FIG. 10, the Q factor is measured every time θ in the Euler angles (0°, θ, 90°) of quartz of the support substrate is changed.

FIG. 12 is a graph showing a relation between θ in the Euler angles of quartz of the support substrate a modification of the third preferred embodiment and the Q factor thereof.

As shown in FIG. 12, it was discovered that the Q factor is high in ranges of 90°≤θ≤170° and 250°≤θ≤270°, for example. The Q factor is similarly high in the case where orientations of the Euler angles of quartz are equivalent to the above. Accordingly, the Q factor is high in a range of 70°≤θ≤170°, for example, due to the crystalline symmetry of quartz. Accordingly, in the present modification, the Q factor can be effectively increased by setting the Euler angles (ϕ, θ, ψ) of quartz of the support substrate 3 to about 0°±10°, 70°≤θ≤170°, 90°±10°.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate;
an intermediate layer on the support substrate;
a piezoelectric layer on the intermediate layer and including a first principal surface and a second principal surface opposed to each other;
a first IDT electrode on the first principal surface of the piezoelectric layer; and
a second IDT electrode on the second principal surface of the piezoelectric layer and opposite to the first IDT electrode; wherein
the support substrate is a quartz substrate with Euler angles (ϕ, θ, ψ) of about 0°±10°, 70°≤θ≤170°, 90°±10°.

2. The acoustic wave device according to claim 1, wherein
the intermediate layer includes a low acoustic velocity layer; and
an acoustic velocity of a bulk wave propagating through the low acoustic velocity layer is lower than an acoustic velocity of a bulk wave propagating through the piezoelectric layer.

3. The acoustic wave device according to claim 2, wherein
the intermediate layer includes a silicon oxide layer.

4. The acoustic wave device according to claim 1, wherein
the intermediate layer includes a high acoustic velocity layer directly contacting the support substrate; and
an acoustic velocity of a bulk wave propagating through the high acoustic velocity layer is higher than an acoustic velocity of an acoustic wave propagating through the piezoelectric layer.

5. The acoustic wave device according to claim 1, wherein the piezoelectric layer is a lithium tantalate layer or a lithium niobate layer.

6. The acoustic wave device according to claim 1, wherein the acoustic wave device is surface acoustic wave resonator, a filter device or a multiplexer including a plurality of acoustic wave resonators.

7. An acoustic wave device comprising:
a support substrate;
an intermediate layer on the support substrate;
a piezoelectric layer on the intermediate layer and including a first principal surface and a second principal surface opposed to each other;
a first IDT electrode on the first principal surface of the piezoelectric layer; and
a second IDT electrode on the second principal surface of the piezoelectric layer and opposite to the first IDT electrode; wherein
the intermediate layer includes a high acoustic velocity layer directly contacting the support substrate;
an acoustic velocity of a bulk wave propagating through the high acoustic velocity layer is higher than an acoustic velocity of an acoustic wave propagating through the piezoelectric layer;
the support substrate is a quartz substrate; and
when λ is a wavelength defined by an electrode finger pitch of the first IDT electrode, a material and a range of thickness of the high acoustic velocity layer are any of combinations in Table 1:
TABLE 1

| Material | Range of thickness t |
|---|---|
| silicon nitride | t ≥ 0.3λ |
| aluminum oxide | t ≥ 0.5λ |
| polycrystalline silicon | t ≥ 0.45λ |
| silicon carbide | t ≥ 0.4λ. |

8. The acoustic wave device according to claim 7, wherein
the intermediate layer includes a low acoustic velocity layer between the high acoustic velocity layer and the piezoelectric layer; and
an acoustic velocity of a bulk wave propagating through the low acoustic velocity layer is lower than an acoustic velocity of a bulk wave propagating through the piezoelectric layer.

9. The acoustic wave device according to claim 7, wherein the piezoelectric layer is a lithium tantalate layer or a lithium niobate layer.

10. The acoustic wave device according to claim 7, wherein the acoustic wave device is surface acoustic wave resonator, a filter device or a multiplexer including a plurality of acoustic wave resonators.

11. An acoustic wave device comprising:
a support substrate;
an intermediate layer on the support substrate;
a piezoelectric layer on the intermediate layer and including a first principal surface and a second principal surface opposed to each other;
a first IDT electrode on the first principal surface of the piezoelectric layer; and
a second IDT electrode on the second principal surface of the piezoelectric layer to be opposed to the first IDT electrode; wherein
the intermediate layer includes a high acoustic velocity layer directly contacting the support substrate;
an acoustic velocity of a bulk wave propagating through the high acoustic velocity layer is higher than an acoustic velocity of an acoustic wave propagating through the piezoelectric layer; and
the support substrate is a quartz substrate with Euler angles (ϕ, θ, ψ) of about 0°±10°, 180°≤θ≤240°, 90°±10°.

12. The acoustic wave device according to claim 11, wherein
the intermediate layer includes a low acoustic velocity layer between the high acoustic velocity layer and the piezoelectric layer; and
an acoustic velocity of a bulk wave propagating through the low acoustic velocity layer is lower than an acoustic velocity of a bulk wave propagating through the piezoelectric layer.

13. The acoustic wave device according to claim 11, wherein the piezoelectric layer is a lithium tantalate layer or a lithium niobate layer.

14. The acoustic wave device according to claim 11, wherein the acoustic wave device is surface acoustic wave resonator, a filter device or a multiplexer including a plurality of acoustic wave resonators.

15. An acoustic wave device comprising:
a support substrate;
an intermediate layer on the support substrate;
a piezoelectric layer on the intermediate layer and including a first principal surface and a second principal surface opposed to each other;
a first IDT electrode on the first principal surface of the piezoelectric layer; and
a second IDT electrode on the second principal surface of the piezoelectric layer and opposite to the first IDT electrode; wherein
the intermediate layer includes a high acoustic velocity layer directly contacting the support substrate;
an acoustic velocity of a bulk wave propagating through the high acoustic velocity layer is higher than an acoustic velocity of an acoustic wave propagating through the piezoelectric layer; and
the support substrate is a quartz substrate with Euler angles (ϕ, θ, ψ) of about 0°±10°, 100°≤θ≤150°, 0°±10°.

16. The acoustic wave device according to claim 15, wherein
the intermediate layer includes a low acoustic velocity layer between the high acoustic velocity layer and the piezoelectric layer; and
an acoustic velocity of a bulk wave propagating through the low acoustic velocity layer is lower than an acoustic velocity of a bulk wave propagating through the piezoelectric layer.

17. The acoustic wave device according to claim 15, wherein the piezoelectric layer is a lithium tantalate layer or a lithium niobate layer.

18. The acoustic wave device according to claim 15, wherein the acoustic wave device is surface acoustic wave resonator, a filter device or a multiplexer including a plurality of acoustic wave resonators.
